(19) United States
(12) Patent Application Publication
(10) Pub. No.: US 2024/0038696 A1
(43) Pub. Date: Feb. 1, 2024

(54) Apparatus Including a Capacitor and a Coil, and a System Having Such an Apparatus

(71) Applicant: Infineon Technologies AG, Neubiberg (DE)

(72) Inventors: Hermann Gruber, Wörth a. D. (DE); Marcus Nübling, Olching-Esting (DE); Jörg Busch, Regensburg (DE); Gerrit Utz, Unterhaching (DE)

(21) Appl. No.: 18/225,393

(22) Filed: Jul. 24, 2023

(30) Foreign Application Priority Data
Jul. 29, 2022 (DE) 102022119125.7

(51) Int. Cl. H01L 23/00; H01F 27/32; H01L 29/66; H01L 21/768; H01F 27/29

(52) U.S. Cl. CPC H01L 24/02; H01F 27/32; H01L 29/66174; H01L 21/76829; H01F 27/292; H01L 2224/04042; H01L 2224/05082; H01L 2224/051

(57) ABSTRACT

An apparatus is provided that includes a substrate. In addition, the apparatus includes a first electrically conductive path arranged in a second layer above the substrate and forming a first connection of the apparatus, and a second electrically conductive pad arranged in the second layer and forming a second connection of the apparatus. An electrically conductive element is arranged in a first layer spaced apart from the second layer. The electrically conductive element forms a first capacitor with either the first pad or the second pad. In addition, a first coil is arranged in the first layer, the second layer, or in both layers. A first end of the first coil is connected to the second pad.

### TECHNICAL FIELD

The present application relates to apparatuses that comprise a coil and a capacitor, and to systems that use such an apparatus to couple circuit sections associated with different voltage domains.

### BACKGROUND

Apparatuses that comprise a capacitor and a coil are used for various applications, for example for resonant circuits. A further application is the DC isolation of different voltage domains, i.e., different circuit sections operating at different supply voltages. Here, the capacitors can be used to decouple DC voltages, while AC signals, in particular radio-frequency (RF) signals, can be transmitted. In the case of a differential configuration, in which differential signals are transmitted, a filter containing coils and also capacitors can then be used to bring about common-mode rejection.

Such capacitors and coils can be provided as discrete devices, which can sometimes mean additional space requirement or can be more complex in terms of assembling systems.

### SUMMARY

According to one exemplary embodiment, an apparatus is provided, comprising: a substrate; a first electrically conductive pad, which is arranged in a second layer above the substrate and forms a first connection of the apparatus; a second electrically conductive pad, which is arranged in the second layer and forms a second connection of the apparatus; a first electrically conductive element arranged in a first layer, which is spaced apart from the second laver, wherein the first electrically conductive element forms a first capacitor with either the first pad or the second pad; and a first coil formed in the first layer and/or the second layer, a first end of the first coil being connected to the second pad.

According to a further exemplary embodiment, a system is provided, comprising: a first circuit section, which is associated with a first voltage domain; a second circuit section, which is associated with a second voltage domain, which is different than the first voltage domain; and the aforementioned apparatus to couple the first circuit section to the second circuit section.

The above summary serves merely as a brief overview of some embodiments and should not be interpreted as limiting.

### BRIEF DESCRIPTION OF THE DRAWINGS

FIG. 1A is a cross-sectional view of an apparatus according to an exemplary embodiment.

FIG. 1B is a schematic plan view of a differential implementation of the apparatus in FIG. 1A.

FIG. 2A is a cross-sectional view of an apparatus according to an exemplary embodiment.

FIG. 2B is a schematic plan view of a differential implementation of the apparatus in FIG. 2A.

FIG. 3A is a cross-sectional view of an apparatus according to an exemplary embodiment.

FIG. 3B is a schematic plan view of a differential implementation of the apparatus in FIG. 3A.

FIG. 4A is a cross-sectional view of an apparatus according to an exemplary embodiment.

FIG. 4B is a schematic plan view of a differential implementation of the apparatus in. FIG. 4A.

FIG. 45 is a perspective view of a portion of the apparatus from. FIG. 4B.

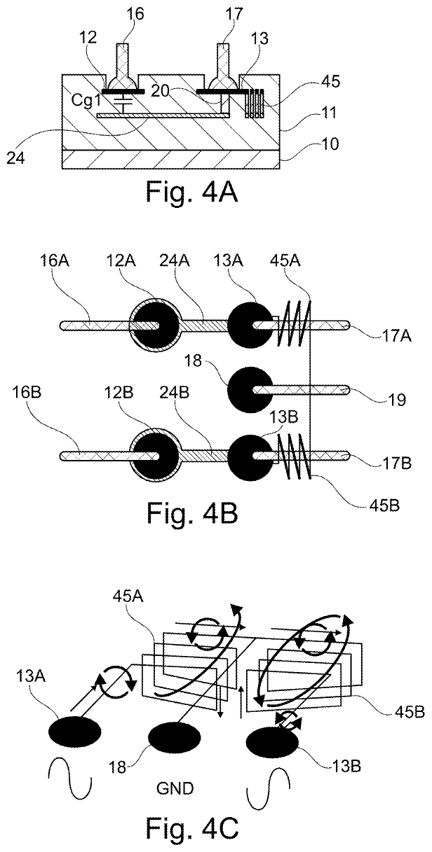

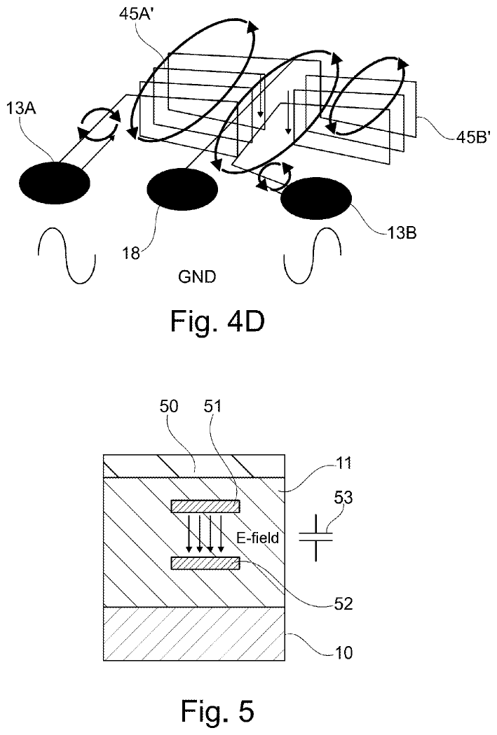

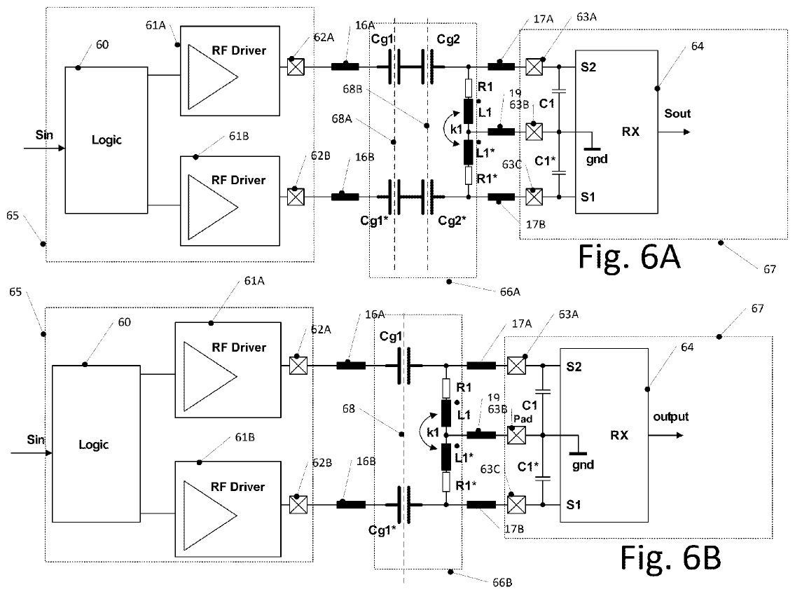

FIG. 4D is a perspective view of a portion of the apparatus from. FIG. 4B according to an alternative implementation.

FIG. 5 illustrates the implementation of capacitors.

FIGS. 6A and 6B show exemplary embodiments of systems.

### DETAILED DESCRIPTION

Various exemplary embodiments are described below with reference to the drawings. These exemplary embodiments serve merely as an explanation and should not be interpreted as limiting. Features (e g elements, components, steps, processes, etc.) of different exemplary embodiments can be combined with one another unless indicated otherwise. Details or modifications described for one of the exemplary embodiments can also be applied to other exemplary embodiments and are therefore not explained repeatedly. Mutually corresponding features bear the same reference signs in different figures and are therefore likewise not explained in detail multiple times.

Couplings or connections described in regard to the exemplary embodiments relate to electrical couplings or connections unless Indicated otherwise.

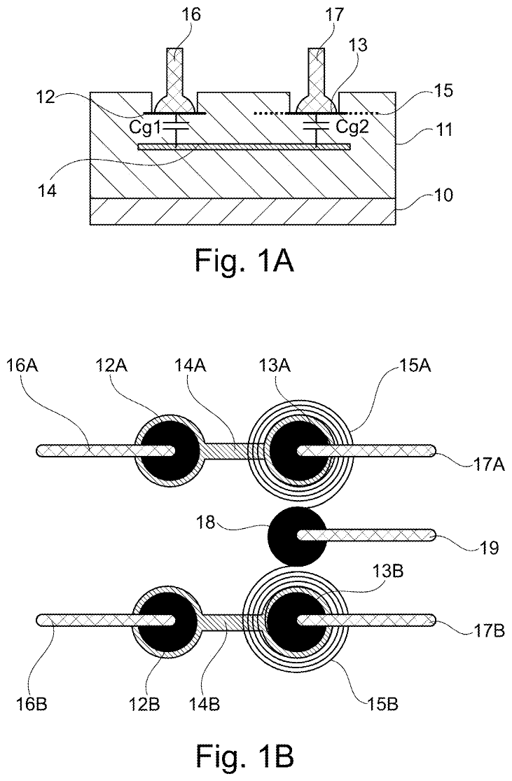

FIG. 1A shows a cross-sectional view of an apparatus according to an exemplary embodiment.

The apparatus in FIG. 1A comprises a substrate 10. The substrate 10 can be a semiconductor substrate such as a silicon substrate. Arranged above the substrate 10 and in a manner spaced apart from the substrate is a first layer, in which an electrically conductive element 14 is arranged. At a further interval from this first layer, in a second layer, a first electrically conductive pad 12 and a second electrically conductive pad 13 are formed. The electrically conductive element 14 is surrounded by a dielectric 11, which is arranged in particular between the substrate 10 and the electrically conductive element 14, and also between the electrically conductive element 14 and the pads 12, 13. While a single continuous dielectric 11 is shown in FIG. 1A, other exemplary embodiments can have provision for multiple sections that comprise different dielectric materials. By way of example, a first dielectric material may be provided between the substrate 10 and the electrically conductive element 14, and a second dielectric material, which is different than the first dielectric material, may be provided between the electrically conductive element 14 and the pads 12, 13.

In some exemplary embodiments, the first and second layers are metal layers, and so the electrically conductive element 14 and also the pads 12 and 13 are made from metal. In other exemplary embodiments, other electrically conductive materials, for example highly doped polycrystalline silicon, can be used in the first layer and/or the second layer. The dielectric 11 may be silicon dioxide or silicon nitrite, for example.

The dielectric 11 and also the pads 12, 13 and the electrically conductive element 14 can be manufactured in a conventional back end of line (BEOL) semiconductor process. The production of integrated circuits or other semiconductor devices is often divided into at least two phases, comprising the front end of line (FEOL) and the BEOL phase. After the BEOL, there may be an additional backend process, also referred to as “post-fab”. FEOL denotes a first phase of production, in which a typical semiconductor process involves configuring individual devices, for example transistors (which includes gate formation, for example), resistors and/or mechanical structures for micro-electromechanical systems (MEAS) in a semiconductor wafer. However, the FEOL does not comprise applying metal connecting layers. The BEOL, as used here, is a second phase of production, which generally starts when the first metal layer is applied to the semiconductor wafer. In a conventional semiconductor process, the BEOL comprises the formation of contacts, insulating layers (for example of oxides or nitrites such as the dielectric 11), metal layers such as the first layer and the second layer and connecting points for connecting the chip and the package. For example, some processes involve adding up to ten metal layers in the BEOL, dielectric layers being situated between the metal layers in each case, although fewer metal layers can also be used, depending on the process. In exemplary embodiments of the present application that are described below, two metal layers with a dielectric between them and possibly plated through holes (VIAs, Vertical Interconnect Accesses) between the layers can be used.

As already mentioned above, the electrically conductive element 11 is thus formed in a first metal layer and the pads 12, 13 are formed in a second metal layer, the formation of the metal layers and the structuring thereof being able to take place as in conventional BEOL processes.

In the exemplary embodiment in FIG. 1A, the first pad 12 is spaced apart from the electrically conductive element 14 by the dielectric 11, and the second pad 13 is likewise spaced apart from the electrically conductive element 14 by the dielectric 11. This forms two plate capacitors, denoted by Cg1 and Cg2 in FIG. 1A.

In addition, a coil 15 is formed around the pad 13 in the second metal layer, one end of the coil 15 being connected to the pad 13. As such, a BEOL process can be used with two metal layers to form a combination comprising two capacitors and one coil. For contact-connection purposes, the pads 12, 13 can be contact-connected to bonding wires 16, 17, as shown in FIG. 1A, with the result that the pads 12, 13 are used as connections of the apparatus. This is only one example of a contact-connection, and other types of contact-connection, for example by means of metal rails, elements of a printed circuit board or a ball grid array (BGA), are also possible.

As a further illustration, FIG. 1B shows a plan view of the exemplary embodiment in FIG. 1A, there being a differential implementation in FIG. 1B, i.e. the arrangement shown in cross section in FIG. 1A is present twice. To distinguish between the two arrangements, FIG. 1B uses the same reference signs as FIG. 1A, an “A” being appended to the reference sign for the first arrangement and a “B” being appended to the reference sign for the second arrangement. FIG. 11 would then be a cross-sectional view along a line defined by the bonding wires 16A and 17A or along a line defined by the bonding wires 16B and 17B, for example. In other exemplary embodiments, single-pole implementations, in which the elements in FIG. 1A are present only once, are also possible.

In the example in FIG. 1B, the pads 12A, 13A, 12B and 13B are in circular form. Other shapes, for example rectangular or square shapes, are also possible. Beneath the pads 12A, 13A, 12B, 13B, the electrically conductive element is likewise in circular form, with a similar diameter to the respective pads, for example +/−10%. Here too, other shapes are possible. The turns of the coils 15A, 15B are arranged circumferentially around the respective pad 13A, 13B, i.e. the coils 15A, 15B are wound around the respective pad 13A, 13B and have their inner end connected to the pad. The two arrangements are designed in accordance with one another, for example with point symmetry with respect to the center of a pad 18 in the plan view in FIG. 1B, and so the turns of the coils 15A, 15B in the example shown have identical winding directions, specifically counterclockwise from the respective pad 13A, 1311. In some applications, this leads to opposite current flow in the mutually facing portions of the coils 15B. In other implementations, the winding direction can be opposite.

The second ends of the coils 15A, 15B are both connected to a further pad 18, which is contact-connected by way of a bonding wire 19. As will be explained later with reference to FIGS. 6A and 6B, such an apparatus is suitable in particular for the DC isolation of different voltage domains, the apparatus then being able to be used to transmit radio-frequency signals. In principle, apparatuses such as those shown in FIGS. 1A and 1B can be employed wherever combinations of capacitors and coils are needed, however.

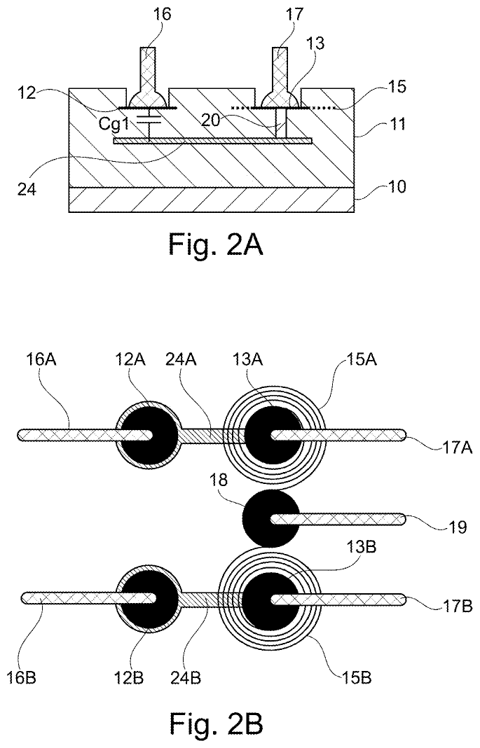

Before the application to the coupling of voltage domains is discussed, various modifications of the exemplary embodiment in FIGS. 1A and 1B will be explained below with reference co FIGS. 2A to 4D, with respective subfigures. To avoid repetitions, only the differences over the exemplary embodiment in FIGS. 1A and 1B, or differences between other exemplary embodiments, will be discussed and the whole apparatus will not be described again.

FIG. 2A shows an apparatus according to a further exemplary embodiment in a cross-sectional view corresponding to the cross-sectional view in FIG. 1A. In the exemplary embodiment in FIG. 2A, the second pad 13 is directly electrically connected to the electrically conductive element 24 by way of a vertical plated-through hole (VIA, Vertical Interconnect Access 20) as a vertical electrically conductive connection, and so here no capacitor is formed. This is thus an exemplary embodiment with only one capacitor Cg1, while the second capacitor Cg2 in FIG. 1A is replaced by a direct. electrical connection. The electrically conductive element is denoted by the reference sign 24 here and by 24A or 24B in FIG. 2B, which shows a plan view corresponding to FIG. 1B. In contrast to the electrically conductive element 14 (14A, 14B) in FIGS. 1A and 1B, the electrically conductive element 24, 24A, 24B does not have a circular shape beneath the pad 13, 13A, 13B, since here just one electrical contact is produced and no capacitor is formed.

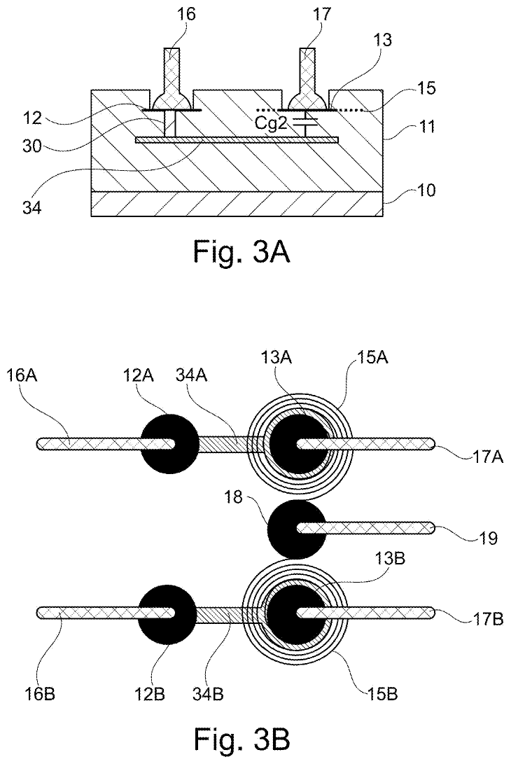

FIGS. 3A and 3B show a further exemplary embodiment, FIG. 3A showing a cross-sectional view corresponding to FIGS. 1A and 2A and. FIG. 3B showing a plan view corresponding to FIGS. 1B and 2B. The electrically conductive element is denoted by the reference signs 34, 34A, 34B here. In contrast to FIG. 1A, the first pad 12 is connected to the electrically conductive element 34 by way of a plated-through hole 30 in FIG. 3A, and so here only the capacitor Cg2 is formed. Accordingly, the electrically conductive element 34, 34A, 34B, as shown in FIG. 3B, does not need to have a circular shape beneath the pads 12A, 12B, since here only the electrical contact-connection is involved.

A further exemplary embodiment is shown in FIGS. 4A to 4D. FIG. 4A shows a cross-sectional view corresponding to the cross-sectional views in FIGS. 1A, 2A and 3A, and FIG. 4B shows a plan view corresponding to FIGS. 1B, 2B and 3B.

The exemplary embodiment in FIGS. 4A to 4D differs from the other exemplary embodiments with regard co the implementation of the coils, as will be explained in more detail below. With regard to the form of one capacitor or two capacitors and the use of plated-through holes, the apparatus in the exemplary embodiment shown is configured as in FIGS. 2A and 2B, i.e. with the plated-through-hole 20. A configuration as in FIGS. 1A, 1B with two capacitors Cg1, Cg2 or as in FIGS. 3A and 3B with the plated-through-hole 30 and the capacitor Cg2 may likewise be provided.

The coils in FIGS. 4A and 4B are denoted by the reference sign 45 (or 45A, 45B in FIG. 4B). As can be seen in FIG. 4A, the coil 15 is not arranged in a planar manner in the second layer, but rather is formed in the first and second layers, together with plated-through-holes.

For the purpose of illustration, FIG. 4C shows a perspective view of a possible implementation of the coils 45A, 45B together with the pads 13A, 13B and 18. As in the case of preceding exemplary embodiments, the coils in this case have opposite winding senses when respective difference signals (i.e. signals phase-shifted through 180′) are applied to the pads 13A, 13B and a reference-ground potential such as ground (GND, Ground) is applied to the pad 18 (clockwise for the coil 45A and counterclockwise for the coil 45B from the perspective of FIG. 4C). Straight arrows indicate the current flow, and curved arrows indicate the generated magnetic field. As can be seen in FIG. 4C, the coils 45A, 45B consist of conductor portions in the first layer and the second layer that are connected to appropriate plated-through holes.

FIG. 4D shows an alternative implementation of the coils, denoted as coils 45A′, 45B′ in FIG. 4D, in this case with the same winding sense for the turns (clockwise in each case).

In FIGS. 1A to 4D (with applicable subfigures), the capacitors are configured as place capacitors, the plates being formed in the first layer (electrically conductive element 14, 24, 34) and the second layer (pads 12 and/or 13). This is once again shown in FIG. 5 using metallic plates 51, 52 in two metal layers within the dielectric 11 above the same substrate 10. This forms a capacitor 53. The reference sign 50 denotes an optional passivation layer, which may also be provided in the case of the exemplary embodiments in FIGS. 1A to 4D. During operation, there is then an electrical field (“E-field”) between the metallic plates 51, 52.

As already mentioned at the outset, the apparatuses explained with reference to FIGS. 1A to 5 can be used for the DC isolation of different circuit portions, in particular in the case of different voltage domains. Applicable systems are shown in FIGS. 6A and 6B. Differential arrangements are used. in each of FIGS. 6A and 6B, as shown in the plan views in FIGS. 1B, 2B, 3B and 4B.

The apparatus in this case is used to couple the signaling of and to DC isolate a first circuit portion 65 from a second circuit portion 67. In FIG. 6A, an apparatus 66A is used that is implemented as in FIGS. 1A and 1B, for example, i.e. with two capacitors Cg1, Cg2. In FIG. 6A, the capacitors of the first portion of the apparatus (for example the apparatus in FIG. 1B formed by the components denoted by suffix “A”) are denoted by Cg1, Cg2, and the capacitors of the second portion of the apparatus (shown with suffix B in FIG. 1B) are denoted by Cg1*, Cg2*. The first coil, for example 15A in FIG. 2B, is represented by an inductance L1 and a resistor R1 in FIG. 6A, and the second coil (for example 15B in FIG. 1B) is represented by an inductance L1* and a resistor R1*. The resistors R1, R1* can represent the nonreactive resistance of the coils, for example.

Dashed lines 68A, 68B represent the DC isolation.

An apparatus 66B having only one capacitor is used in FIG. 6B, for example the apparatus in FIGS. 2A and 23 or the apparatus in FIGS. 4A and 4B with the capacitor Cg1. Similarly, the apparatus in FIGS. 3A and 3B with the capacitor: Cg2 can also be used. There is then only one DC isolation here, represented by the dashed line 68. The coils (for example 15A, 15B or 45A, 45B) axe again represented by the inductance L1, L1* and the resistors R1, R1*, as explained for FIG. 6A. Apart from the different number of capacitors, the apparatus in FIG. 6B corresponds to the apparatus in FIG. 6A, and mutually corresponding elements bear the same reference signs. Therefore, only FIG. 6A is now explained below, and the explanations also relate to FIG. 6B accordingly.

In some exemplary embodiments, the first circuit portion 65, the second circuit portion 61 and the apparatus 66A or 66B are implemented on different dies, and/or also arranged in separate packages. The apparatus 66A, 66B can therefore provide a separate coupling chip, so to speak. In other exemplary embodiments, the apparatus 66A, 66B may be implemented together with the first circuit portion 65 and/or the second circuit portion 67 on a common die. The coupling chip can also be referred to as a coupler chip.

In the example shown, the first circuit section 65 comprises a logic circuit: 60, a first radio-frequency driver 61A and a second radio-frequency driver 61B. The logic circuit 60 receives a signal Sin that ultimately needs to be transmitted to the second circuit section 67, and encodes said signal for the transmission. Such encoding can take place in any conventional manner and can also include techniques such as noise shaping, for example. The logic circuit 60 generates a difference signal containing two signal portions, which are output to the radio-frequency drivers 61A and 61B, which then output a differential radio-frequency signal on output pads 62A, 62B.

The pads 62A, 62B are connected to the apparatus 66A or 66B, specifically to the pads 12A, 12B in the figures described hereinabove, by way of the bonding wires 16A, 16B. The radio-frequency signals are then transmitted by way of the capacitors Cg1, Cg2, Cg1*, Cg2* in the case of FIG. 6A or by way of the capacitors Cg1, Cg1* in FIG. 6B, while DC voltage components are blocked by the capacitors.

The apparatus 66A or 66B is connected to pads 63A, 63B, 63C of the second circuit section 67 by way of the bonding wires 17A, 19 and 17B as shown. With reference to FIG. 1B, for example, the pad 13A is thus also connected to the pad 63, the pad 18 is connected to the pad 63B and the pad 13B is connected to the pad 63C.

In the second circuit portion 67, the pad 63A is connected to the pad 63B by way of a capacitor C1, and the pad 63B is connected to the pad 63C by way of a capacitor C1*. In the exemplary embodiment shown, the capacitors C1, C1* together with the inductances L1, L1* and the resistors R1, R1* act as an RLC filter circuit, which can reject a common-mode component of the differential signal. Such common-mode components can occur during transmission and, if not filtered out, can cause high voltages in the circuit section 67, which can lead to damage. k1 denotes a coupling between the inductances L1 and L1*. This design of coils and capacitors can thus ensure common-mode rejection.

The transmitted signals are then supplied to connections S1, S2 of a receiving circuit 64, which uses them to generate—for example by way of demodulation and decoding—an output signal Sout that can correspond to the signal Sin in the event of error-flee transmission. The transmission. circuits shown in the first and second circuit sections should be understood only as an application example, however, and other circuits can also be used. Moreover, as already mentioned earlier on, instead of the bonding wires 16A, 16B, 17A, 17B, 19 it is also possible to use other electrical connections such as metal rails, circuit boards printed with metal tracks, connections in ball grid arrays and the like.

In some exemplary embodiments, the circuit section 65 may be associated with a first voltage domain, and the second circuit section 67 may be associated with a second voltage domain, i.e. the circuit sections 65 and 61 can have separate Power supplies. Voltages in the first and second voltage domains can differ significantly in some applications, for example by a factor of 10 or a factor of 100. By way of example, the first circuit section 65 may be associated with a high-voltage domain, while the second circuit section 67 is associated with a low-voltage domain. The apparatus 66A or 66B then ensures DC isolation of the voltage domains.

Some embodiments are defined by the examples that follow:

Example 1. Apparatus, comprising: a substrate, a first electrically conductive pad, which is arranged in a second layer above the substrate and forms a first connection of the apparatus, a second electrically conductive pad, which is arranged in the second layer and forms a second connection of the apparatus, a first electrically conductive element arranged in a first. layer, which is spaced apart from the second layer, wherein the first electrically conductive element forms a first capacitor with either the first pad or the second pad, and a first coil formed in the first layer and/or the second layer, a first end of the first coil being connected to the second pad.

Example 2. Apparatus according to example 1, wherein the first electrically conductive element forms a second capacitor with the other of the first pad and the second pad.

Example 3. Apparatus according to example 1, wherein the first electrically conductive element is connected to the other of the first pad and the second pad by a vertical electrically conductive connection.

Example 4. Apparatus according to one of examples 1 to 3, wherein the first coil is formed in the second layer and turns of the first coil are arranged circumferentially around the second pad.

Example 5 Apparatus according to one of examples 1 to 3, wherein turns of the first coil are formed by electrically conductive sections in the first layer, electrically conductive sections in the second layer and vertical electrically conductive connections between the first layer and the second layer.

Example 6. Apparatus according to one of examples 1 to 5, further comprising: a third electrically conductive pad, which is arranged in the second layer and forms a third connection of the apparatus, a fourth electrically conductive pad, which is arranged in the second layer and forms a fourth connection of the apparatus, a second electrically conductive element arranged in the first layer, wherein the second electrically conductive element forms a third capacitor with either the third pad or the fourth pad, and a second coil formed in the first layer and/or the second layer, a first end of the second coil being connected to the fourth pad.

Example 7. Apparatus according to example 6, wherein the third pad, the fourth pad, the second electrically conductive element and the second coil are configured and arranged in accordance with the first pad, the second pad, the first electrically conductive element and the first coil.

Example 8. Apparatus according to example 6 or 7, further comprising: a fifth electrically conductive pad, which is arranged in the second layer and forms a fifth connection of the apparatus, a second end of the first coil and a second end of the second coil being connected to the fifth pad.

Example 9. Apparatus according to one of examples 6 to 8, wherein turns of the first coil have the opposite winding direction to turns of the second coil.

Example 10. Apparatus according to one of examples 1 to 9, wherein the apparatus is configured as a coupler chip for coupling two circuit portions.

Example 11. Apparatus according to one of examples 1 to 10, wherein at least one layer from the first layer and the second layer is a metal layer.

Example 12. Apparatus according to one of examples 1 to 11, wherein a dielectric material is arranged between the first layer and the second layer.

Example 13. Apparatus according to one of examples 1 to 12, wherein a dielectric material is arranged between the substrate and the first layer.

Example 14. System, comprising: a first circuit section, which is associated with a first voltage domain, a second circuit section, which is associated with a second voltage domain, which is different than the first voltage domain, and the apparatus according to one of examples 1 to 13 to couple the first circuit section to the second circuit section.

Example 15. System according to example 14, wherein the first circuit section is formed on a first die, the second circuit section is formed on a second die and the apparatus is formed on a third die.

Example 16. System according to example 14 or 15, wherein the first circuit section is coupled to the first connection of the apparatus and the second circuit section is coupled to the second connection of the apparatus.

Example 17. System according to example 16, wherein the apparatus is configured according to one of examples 6 to 9, the first circuit section being coupled to the third connection of the apparatus and the second circuit section being coupled to the fourth connection of the apparatus.

Example 18. System according to example 17, wherein the apparatus is configured according to example 8, the second circuit section being coupled to the fifth connection of the apparatus.

Example 19. System according to one of examples 14 to 18, wherein the first and second circuit sections are coupled to the apparatus by way of respective bonding wires.

Although this description has illustrated and described specific exemplary embodiments, persons with standard knowledge in the art will recognize that: a large number of alternative and/or equivalent implementations can be chosen as a replacement for the specific exemplary embodiments shown and described in this description without departing from the scope of the invention shown. It is the intention for this application to cover ail adaptations or variations of the specific exemplary embodiments that are discussed here. Therefore, this invention is intended to be restricted only by the claims and the equivalents of the claims.

What is claimed is:

1. An apparatus, comprising:
a substrate;
a first electrically conductive pad arranged in a second layer above the substrate and forming a first connection of the apparatus;
a second electrically conductive pad arranged in the second layer and forming a second connection of the apparatus;
a first electrically conductive element arranged in a first layer spaced apart from the second layer, wherein the first electrically conductive element forms a first capacitor with either the first pad or the second pad; and
a first coil formed in the first layer and/or the second layer, a first end of the first coil being connected to the second pad.

2. The apparatus of claim I, wherein the first electrically conductive element forms a second capacitor with the other one of the first pad and the second pad.

3. The apparatus of claim 1, wherein the first electrically conductive element is connected to the other one of the first pad and the second pad by a vertical electrically conductive connection.

4. The apparatus of claim 1, wherein the first coil is formed in the second layer, and wherein turns of the first coil are arranged circumferentially around the second pad.

5. The apparatus of claim 1, wherein turns of the first coil are formed by electrically conductive sections in the first layer, electrically conductive sections in the second layer, and vertical electrically conductive connections between the first layer and the second layer.

6. The apparatus of claim 1, further comprising a third electrically conductive pad arranged in the second layer and forming a third connection of the apparatus;
a fourth electrically conductive pad arranged in the second layer and forming a fourth connection of the apparatus;
a second electrically conductive element arranged in the first layer, wherein the second electrically conductive element forms a third capacitor with either the third pad or the fourth pad; and
a second coil formed in the first layer and/or the second. layer, a first end of the second coil being connected. to the fourth pad.

7. The apparatus of claim 6, wherein the third pad, the fourth pad, the second electrically conductive element, and the second coil are configured and arranged in accordance with the first pad, the second pad, the first electrically conductive element, and the first coil.

8. The apparatus of claim 6, further comprising:
a fifth electrically conductive pad arranged in the second layer and forming a fifth connection of the apparatus,
wherein a second end of the first coil and a second end of the second coil are connected to the fifth pad.

9. The apparatus of claim 6, wherein turns of the first coil have an opposite winding direction to turns of the second coil.

10. The apparatus of claim 1, wherein the apparatus is configured as a coupler chip configured to couple two circuit portions.

11. The apparatus of claim 1, wherein at least one of the first layer and the second layer is a metal laver.

12. The apparatus of claim 1, wherein a dielectric material is arranged between the first layer and the second laver.

13. The apparatus of claim 1, wherein a dielectric material is arranged between the substrate and the first layer.

14. A system, comprising:
a first circuit section associated with a first voltage domain;
a second circuit section associated with a second voltage domain which is different than the first voltage domain; and
the apparatus of claim 1 to couple the first circuit section to the second circuit section.

15. The system of claim 14, wherein the first circuit section is formed on a first die, the second circuit section is formed on a second die, and the apparatus is formed on a third die.

16. The system of claim 14, wherein the first circuit section is coupled to the first connection of the apparatus, and wherein the second circuit section is coupled to the second connection of the apparatus.

17. The system of claim 16, wherein:
the apparatus further comprises: a third electrically conductive pad arranged in the second layer and forming a third connection of the apparatus; a fourth electrically conductive pad arranged in the second layer and forming a fourth connection of the apparatus; a second electrically conductive element arranged in the first layer, wherein the second electrically conductive element forms a third capacitor with either the third pad or the fourth pad; and a second coil formed in the first layer and/or the second layer, a first end of the second coil being connected to the fourth pad;
the first circuit section is coupled to the third connection of the apparatus; and
the second circuit section is coupled to the fourth connection of the apparatus.

18. The system of claim 17, wherein:
the apparatus further comprises a fifth electrically conductive pad arranged in the second layer and forming a fifth connection of the apparatus;
a second end of the first coil and a second end of the second coil are connected to the fifth pad; and
the second circuit section is coupled to the fifth connection of the apparatus.

19. The system of claim 14, wherein the first and second circuit sections are coupled to the apparatus by way of respective bonding wires.
